(19) United States
(12) Patent Application Publication
(10) Pub. No.: US 2010/0327276 A1
(43) Pub. Date: Dec. 30, 2010

(54) Method and system for passivation of defects in mercury cadmium telluride based optoelectric devices

(75) Inventors: Orin W. Holland, Mount Juliet, TN (US); Terry D. Golding, San Marcos, TX (US); John H. Dinan, Alexandria, VA (US); Ronald Paul Hellmer, Round Rock, TX (US)

Correspondence Address: TOMLINSON & O'CONNELL, P.C., TWO LEADERSHIP SQUARE, 211 NORTH ROBINSON, SUITE 450, OKLAHOMA CITY, OK, 73102, US

(73) Assignee: Amethyst Research, Inc, Ardmore, OK (US)

(21) Appl. No.: 12/831,808

(22) Filed: Jul. 7, 2010

Related U.S. Application Data
(63) Continuation-in-part of application No. 12/715,852, filed on Mar. 2, 2010.
Application No. 12/715,852 is a continuation-in-part of application No. 11/716,205, filed on Apr. 19, 2007.
(60) Provisional application No. 61/223,935, filed on Jul. 8, 2009.

(51) Int. Cl. H01L 29/22; H01L 21/30

(52) U.S. Cl. 257/42; 438/475; 257/E21.212; 257/E29.099

(57) ABSTRACT

Apparatus and method to improve the operating parameters of HgCdTe-based optoelectric devices by the addition of hydrogen to passivate dislocation defects. A chamber and a UV light source are provided. The UV light source is configured to provide UV radiation within the chamber. The optoelectric device, which may comprise a HgCdTe semiconductor, is placed into the chamber and may be held in position by a sample holder. Hydrogen gas is introduced into the chamber. The material is irradiated within the chamber by the UV light source with the device and hydrogen gas present within the chamber to cause absorption of the hydrogen into the material.

### CROSS-REFERENCE TO RELATED APPLICATIONS

The present application is a continuation-in-part of co-pending U.S. patent application Ser. No. 12/715,852, filed Mar. 3, 2010, which is a continuation-in-part of U.S. patent application Ser. No. 11/716,205, filed Apr. 19, 2007, the contents of which are incorporated herein by reference. This application further claims priority to U.S. Provisional Patent Application No. 61/223,935 filed Jul. 8, 2009, the contents of which are incorporated herein by reference.

### FIELD OF THE INVENTION

The present invention is directed to the improvement of Mercury-Cadmium Telluride (hereinafter “HgCdTe”) based devices and components, including those related to optoelectronics and thermal electrics, to specifically improve their operating parameters by the addition of hydrogen.

### SUMMARY OF INVENTION

The present invention is directed to a method for passivation of defects in a material. The method comprises providing a chamber and a UV light source to provide UV radiation into the chamber. The material is placed into the chamber and hydrogenating gas is introduced into the chamber. The material is irradiated within the chamber with the UV light and hydrogenating gas present within the chamber to cause absorption of the hydrogenating gas into the material.

In another embodiment the present invention is directed to a method for hydrogenating a semiconductor. The method comprises providing a vacuum chamber adapted to support the semiconductor. A UV light source is provided. The semiconductor is placed within the chamber and a hydrogenating gas is introduced. The hydrogenating gas is adsorbed on a surface of the semiconductor. The hydrogenating gas is irradiated to dissociate the hydrogenating gas to generate atomic components. Electrons are injected into the vacuum chamber. The atomic components are absorbed within the semiconductor to passivate at least one defect center within the semiconductor.

Further still, the present invention is directed to a Mercury Cadmium Telluride semiconductor device structure comprising a plurality of UV hydrogenated defects.

### BRIEF DESCRIPTION OF THE DRAWINGS

FIG. 1(a) is a chart showing a comparison of deuterium and free carrier concentration profiles in CdTe:As after plasma exposure.

FIG. 1(b) is a chart showing the decomposition of a gallium-nitride material under various experimental conditions.

FIG. 2 is a diagrammatic representation of a system for UV-assisted hydrogenation of a semiconductor material.

FIGS. 3(a), 3(b), 3(c), and 3(d) are graphs of concentration of deuterium in semiconductor materials. These Figures correspond to the following treatment conditions: deuterated (a) with and (b) without UV irradiation, (c) UV irradiated in the absence of deuterium, (d) and untreated.

FIG. 4 is a diagrammatic representation of an apparatus having an internal UV source for UV-assisted hydrogenation of a semiconductor material.

FIGS. 5(a) and 5(b) are graphs of concentration versus depth after exposure to different UV lamps during hydrogen exposure.

FIG. 6 is a diagrammatic comparison of lamp efficacy for activating hydrogenation at 60° C. in HgCdTe material.

FIG. 7 is a diagrammatic representation of the band structure near a dislocation core in a UV-irradiated semiconductor showing the quasi-equilibrium, n-type bulk surrounding the core.

### DETAILED DESCRIPTION

Hydrogenation of thin-film HgCdTe is effective in improving the operation of photodetectors fabricated within the material. This effect is thermally stable and has been observed to survive thermal annealing at 275° C. Post-hydrogenation effects in photodetectors include a decrease in dark current, reverse bias current, and increase in quantum efficiency without dopant deactivation.

UV-activated hydrogenation of semiconductors limits in-diffusion of hydrogen to pathways predominately associated with dislocations or other extended defects. The near absence of bulk diffusion ensures that deactivation of dopant by hydrogen will not occur. This effect is only dependent upon the photo-induced, quasi-equilibrium charge distributions within the semiconductor and therefore is quite general, although it may be affected by the band gap of the material.

Within semiconducting materials hydrogen interacts with broken or weak bonds, such as those found at extended and localized defects to passivate the deleterious effects of such a broken or weak bond. Defects, as used herein, include any structural or chemical variation within the crystalline lattice of the semiconductor that disrupts the three-dimensional repetition of the crystal's unit cell structure. The main result of hydrogenating such defects is the shilling of the energy levels associated with the broken or weak bonds out of the band gap. The band gap separates the valence and conduction band that comprise the electronic energy levels in a semiconductor substantially free from defects. The shift in the energy levels typically lead to the passivation of the electrical activity of defects. The consequences of these interactions are substantial changes in the electrical and optical properties of the materials, including transport properties such as carrier mobility/lifetime. Thus, passivation of defects such as dislocations in hydrogenated semiconductor material provides a range of advantages.

Passivation of deep-level defect states by atomic hydrogen has been observed in a number of semiconductors. Historically, this occurred prior to the observation of shallow-level passivation, especially those levels associated with dopant impurities intentionally introduced to alter the electrical resistivity of the material. (The position of the electron energy level relative to a band edge qualities it as either deep or shallow.) Hydrogen passivation of deep-level states has been observed in Si, Ge, GaAs, GaP, AlGaAs, CdTe, and HgCdTe in attempts to eliminate traps recombination/generation centers to improve the yield and reliability of devices. However, the use of hydrogen passivation in semiconductors has not been considered as a practical global solution to such problems. This is due to issues relating to the activity of hydrogen in devices that has prevented its adoption into manufacturing, especially for passivation of bulk regions in single crystal semiconductors.

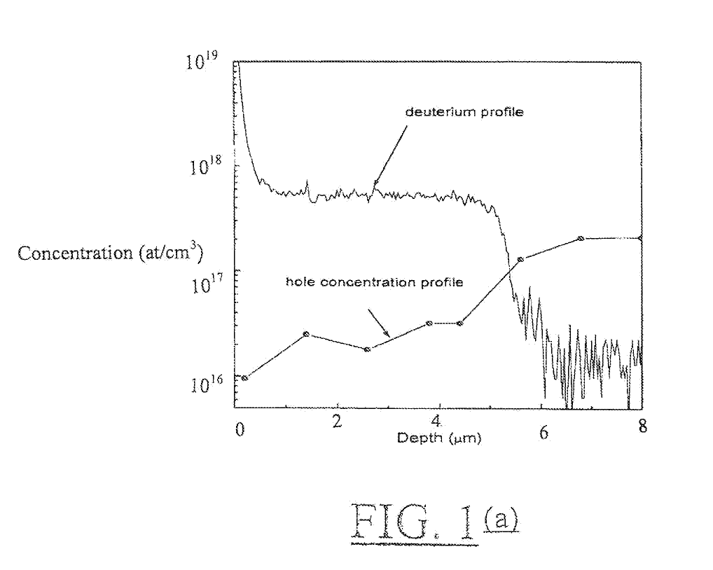

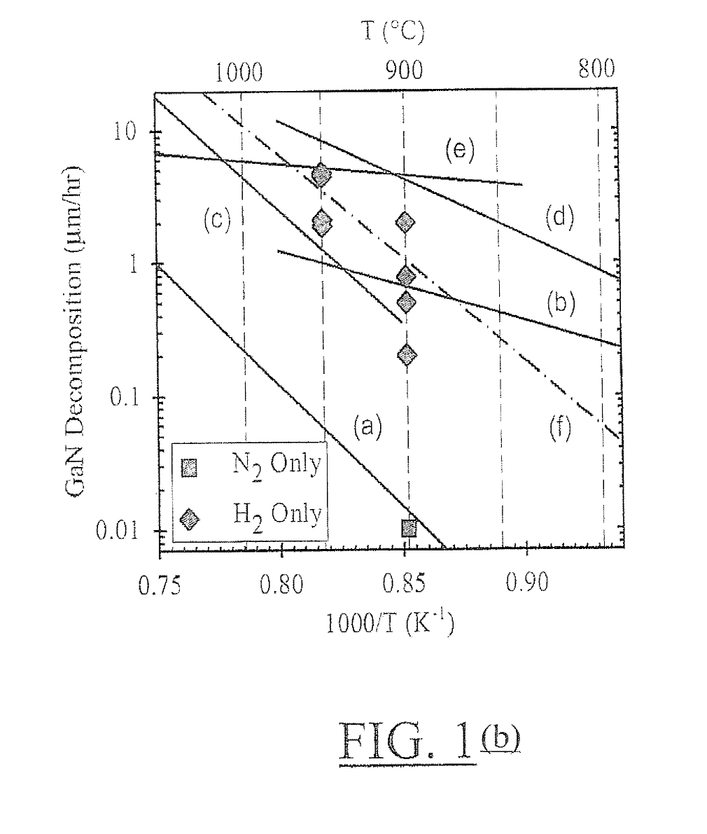

Not only is the thermal stability of the deactivation effect potentially a limiting factor to practical applications for hydrogen passivation but deactivation of dopants remains a critical issue since devices will not operate properly, if at all, without sufficient dopant activation. Dopant deactivation has been reported in II-VI semiconductors. In particular, exposure of arsenic-doped CdTe to a deuterium plasma at 150° C. for 180 min. results in deactivation of the acceptor concentration. This is shown in FIG. 1(a), which compares the deuterium profile in CdTe with the p-type doping concentration. It is clear that formation of As-D complexes results in acceptor deactivation. Thus, it is not obvious to one skilled in the art that hydrogenation of HgCdTe-based devices for defect passivation improves their operability.

Device grade HgCdTe is very difficult to form in bulk and therefore is grown on suitable crystalline substrates by techniques such as liquid-phase epitaxy (LPE) or molecular-beam epitaxy (MBE). However, the quality of epitaxially grown HgCdTe may suffer due to poor substrate quality or mismatch in the lattice parameter of the substrate and the grown thin-film. Defects within the active regions of HgCdTe devices lead to leakage currents even during low temperature operation, i.e. an operability limitation of the focal plane array (“FPA”). As used herein, a focal plane array comprises an image sensing device comprising an array of light-sensitive pixels positioned at the focal plane of a lens. As used herein “focal plane array” may also include two-dimensional array of detectors that are sensitive to light in the infrared spectrum. An infrared FPA may be used in weapons guidance systems, infrared astronomy, manufacturing inspection, thermal imaging, and medical imaging.

HgCdTe diode arrays also suffer from problems related to the lack of a suitable lattice-matched, large-area growth substrate. Due to silicon's availability and low cost, it is considered to be a promising growth substrate for future HgCdTe devices. However, silicon's nineteen percent (19%) lattice parameter mismatch with HgCdTe presents a significant technological hurdle since it leads to defects during growth that degrade the performance of HgCdTe devices. Hydrogenation has been demonstrated to lessen the deleterious effects of these defects. This is commonly referred to as the “passivation” of defects. Hydrogenation appears to solve many of the problems related to HgCdTe devices. However, in order to realize this benefit, cost effective hydrogenation processes must be developed.

Thus, there is a need for improved systems and methods for the passivation of defects in semiconductors introduced during growth. Such defects include those that arise from epitaxial growth of the semiconductor layers on a lattice mismatched substrate, as well as those formed during materials processing. e.g. during IRFPA manufacturing. Benefits of hydrogenation include improving the electrical and optical characteristics of semiconductors. While the bulk of the discussion herein focuses on HgCdTe semiconductors, one skilled in the art will appreciate that hydrogenation methods and systems disclosed herein are applicable to any semiconducting, material or device structure.

The use of UV light to activate hydrogenation of semiconducting materials offers many advantages over previous techniques used for hydrogenating materials. UV-irradiation activates in-diffusion of hydrogen by activating at least two processes related to hydrogenation. Since hydrogen diffuses in semiconductors in its atomic state (H), rather than as a molecule, molecular hydrogen (H₂) should be dissociated prior to in-diffusion. This can occur in the gaseous phase to increase the atomic hydrogen to molecular hydrogen ratio in the process environment within the chamber discussed below or on the semiconductor surface. In addition, molecular hydrogen can adsorb on the surface and, once there, can be dissociated. This can occur in semiconductors as a single coordinated process known as dissociative adsorption, which involves molecular dissociation as an integral part of adsorption. UV activated in-diffusion proceeds via photon induced dissociation of molecular hydrogen either in the gas phase and/or adsorbed on the surface. The amount of energy needed to break apart molecular hydrogen adsorbed on the surface of the semiconductor or activate dissociative adsorption is generally less than the amount required to break apart (dissociate) molecular hydrogen in the gaseous phase.

Photon-assisted hydrogenation (PAH) offers a number of unique processing advantages that essentially derive from the unique properties of light. The first involves the directionality of light that can be utilized with a simple shadow masking technique to yield a selective-area process. Selective-area hydrogenation is important since device regions that might be degraded by hydrogenation, e.g. metal runs on a chip, can be protected.

Another advantage of UV activated processing is its selectivity. Selectivity of the process may be controlled by the photon energy (wavelength) chosen to target activation of a specific process to enhance the selected-area processing. An example is the use of a low pressure Hg lamp to activate dissociation of molecular hydrogen in the gaseous phase. A low pressure Hg lamp emits UV radiation in a wavelength range of 185 and 254 nm ideal for dissociating molecular H₂.

Furthermore. UV-activated hydrogenation is inherently a low-temperature process, especially if the rate-limiting step is molecular hydrogen dissociation. Process temperatures for UV-activated hydrogenation may be below 100 degrees Celsius and preferably are in a range considered “room temperature.” Low-temperature hydrogenation offers a number of advantages. First, it limits hydrogen- or thermal-induced etching of the material or nearby surfaces. For example, hydrogen exposure of a GaN material at high-temperature causes substantial decomposition of the material, as shown in FIG. 1(b). Low-temperature processing eliminates or reduces this effect. Also, in addition to the minimal etching of the device surface, low-temperature hydrogenation also minimizes etching from all nearby surfaces (chamber walls, substrate mount etc), thereby reducing the risk of redeposition of these materials onto the substrate itself. For example, plasma-activated hydrogenation can leave thin film coatings on ceramic standoffs, as evidenced by discoloration that occurs over time. These problems have not been observed during UV-activated hydrogenation of semiconducting materials. Furthermore, low-temperature processing is desirable since it avoids any thermally-activated chemical or structural changes, such as intermixing in a heterostructure, in the processed material.

Dissociation of hydrogen by UV light also results in the generation of neutral atomic hydrogen. Other techniques such as use of plasma result in substantial amounts of ionized hydrogen (hydrogen ions having either a positive or negative charge). Ionized hydrogen may be more reactive but it also results with charging of the semiconductor material. Charging the material can damage sensitive electronic structures on or within the semiconductor. Thus, UV-activated hydrogenation results in less charging of the semiconductor material during processing and thus reduces or eliminates the possibility of damaging charge-sensitive devices.

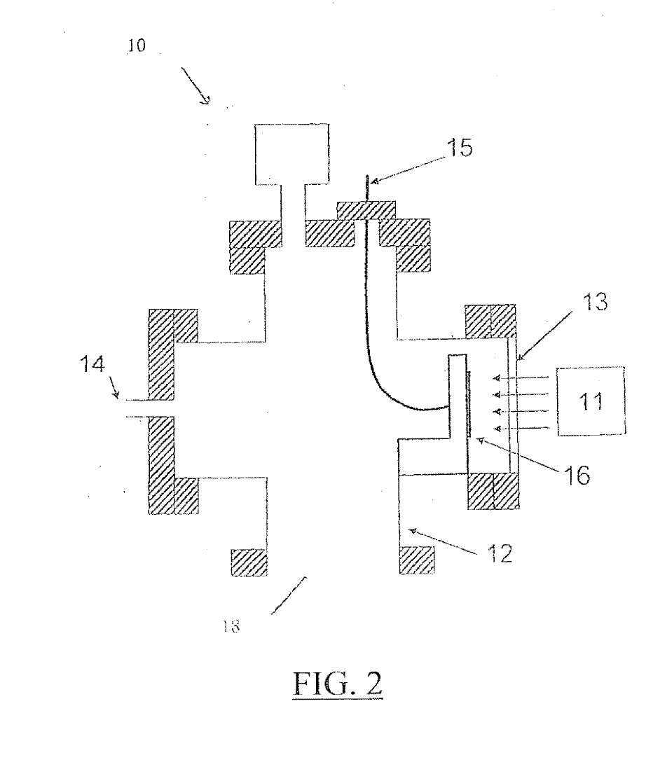

Turning now to FIG. 2, an apparatus suitable for UV hydrogenation of a semiconductor, and particularly the passivation of defects in a semiconductor such as HgCdTe, is illustrated in FIG. 2. System 10 has chamber 12 and UV light source 11, which may be a mercury, deuterium or xenon lamp. The choice of lamp used by the method of the present invention is dictated by its spectral output. In general, deep UV light sources for photochemical processing usually operate in the wavelength range of 100-400 μm. For hydrogenation, the spectral output of the lamp should be predominantly at wavelengths less than 300 nm. The dissociation energy of molecular hydrogen corresponds to that of a photon with a wavelength of 275 nm. Thus, a UV lamp having a spectral output at a wavelength of 275 nm or less is preferred to ensure dissociation of hydrogen molecules in the gas phase.

For a given set of process conditions, increasing the intensity of the UV irradiation enhances the photochemical processing rate. Exposure can either be done using broad-band sources with continuous output over a finite spectra window, or a narrow-band or monochromatic sources with distinct and well-defined emission lines. Photochemical reactions generally activate a surface-related process such as photo-dissociation of a reactive process gas or photo enhancement of a surface-related process (reaction or desorption). The irradiation wavelength or spectrum should be optimized for a given process in order to effectively excite the gas molecules and/or activate the surface reaction/desorption. In the case of UV-activated hydrogenation, surface-activated processes may include cracking of molecular hydrogen adsorbed on the semiconductor surface or in the gas phase near the surface. Since the solubility and diffusivity of atomic hydrogen is much greater than its molecular counterpart, the increased concentration of atomic hydrogen results in substantially enhanced rates of hydrogenation.

When processing the material at a temperature above room temperature, chamber 12 may be wrapped with heating tape and aluminum foil (not shown) to achieve desired processing temperatures. A heated platen (sample holder) can also be used to achieve the desired temperature of the material during processing. As shown in FIG. 2, a thermocouple 15 may be positioned within the chamber to measure the temperature of the semiconductor 16.

The UV light emitted from light source 11 may pass into the chamber 12 through a viewport 13. The viewport 13 may comprise 6-inch fused silica to allow transmission of UV light down to wavelengths of about 200 nm. A gas inlet 14 provides for introduction of hydrogen (or deuterium) gas into the chamber 12. An opening 18 connects to a gate valve and a turbo pump (not shown).

Deuterium, rather than hydrogen, was used to improve resolution, and distinguish from background hydrogen during Secondary Ion Mass Spectroscopy (SIMS) depth analysis. Two samples were heated in the presence of deuterium, but not exposed to UV, and were intended as control samples. Another control sample was completely untreated. The structure of the samples, the temperature of the test, and the environment are shown in Table I. Some samples were capped with CdTe. Typically CdTe capping of the HgCdTe wafer provides a protective layer to act as an antireflective coating and an insulator for interconnect metals.

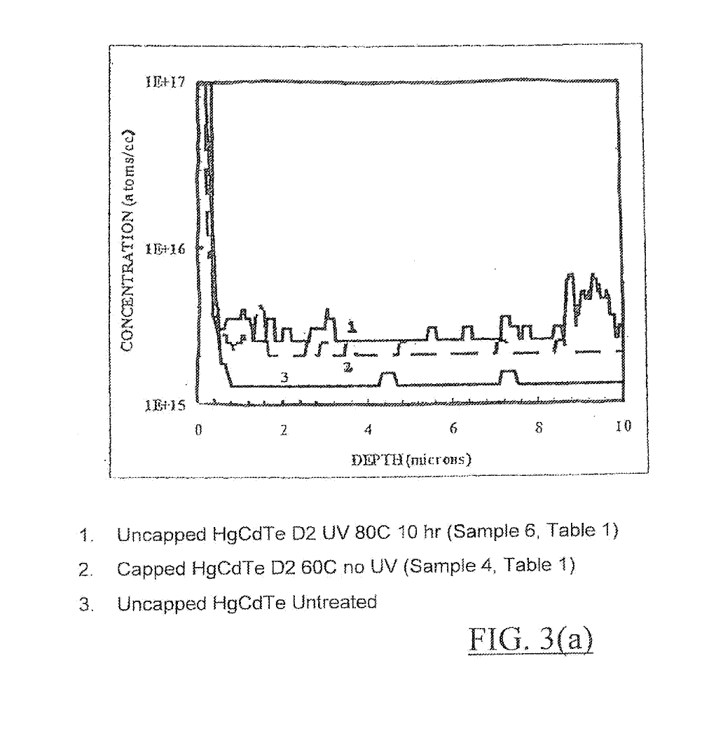

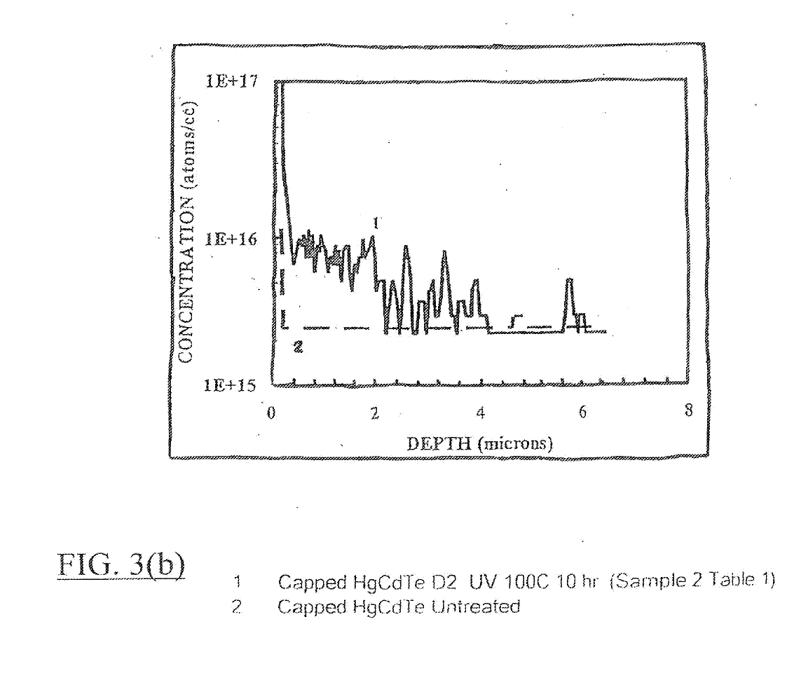

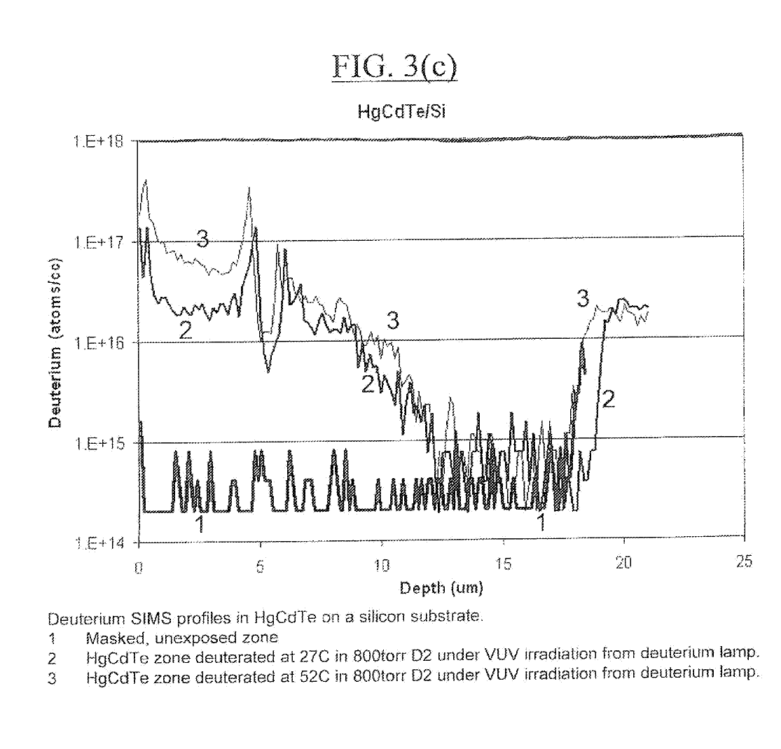

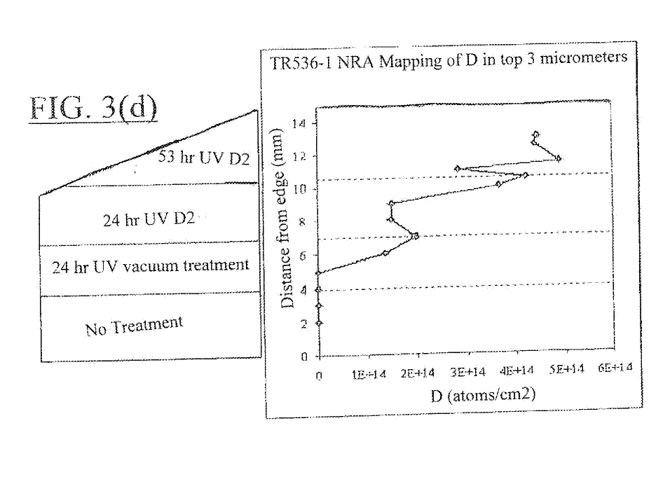

Sample temperatures were varied between 60-100° C. for samples with a CdTe capping layer and 60-80° C. for samples without the capping layer. Smoothed SIMS profile data for the two samples are shown in FIGS. 3(a) and 3(b). Deuterium pressure for all treatments was 761 Torr. In the absence of UV radiation, no deuterium was detected in the capped HgCdTe epilayer after treatment at 60° C. (curve 2 of FIG. 3(a)). With UV, an uncapped layer treated in deuterium for 10 hours at 80° C. showed some deuterium—see curve 1 of FIG. 3(a), but not as much as after treatments at a higher temperature. An untreated sample showed no deuterium (curve 3 of FIG. 3(a))

When a CdTe capped material was irradiated with UV at 100° C. for 10 hours, deuterium concentration increased several-fold to a depth of two (2) microns (curve 1, FIG. 3(b)) compared with an untreated sample (curve 2, FIG. 3(b)).

TABLE I
Structure and Treatment Conditions for UV Hydrogenation Studies

| Sample | Structure | Temp/(° C.) | Environment* |
|---|---|---|---|
| 0 | CdTe/HgCdTe/Si | 60 | No exposure |
| 1 | CdTe/HgCdTe/Si | 80 | D environment, UV |
| | | | exposure |
| 2 | CdTe/HgCdTe/Si | 100 | D environment, UV |
| | | | exposure |
| 3 | CdTe/HgCdTe/Si | 80 | D environment, UV |
| | | | exposure |
| 4 | CdTe/HgCdTe/Si | 60 | D environment, no |
| | | | UV |
| 5 | HgCdTe/Si | 60 | D environment, UV |
| | | | exposure |
| 6 | HgCdTe/Si | 80 | D environment, UV |
| | | | exposure |
| 7 | HgCdTe/Si | 60 | D environment, no |
| | | | UV |
| 8 | HgCdTe/Si | 60 | D environment, UV |
| | | | exposure |

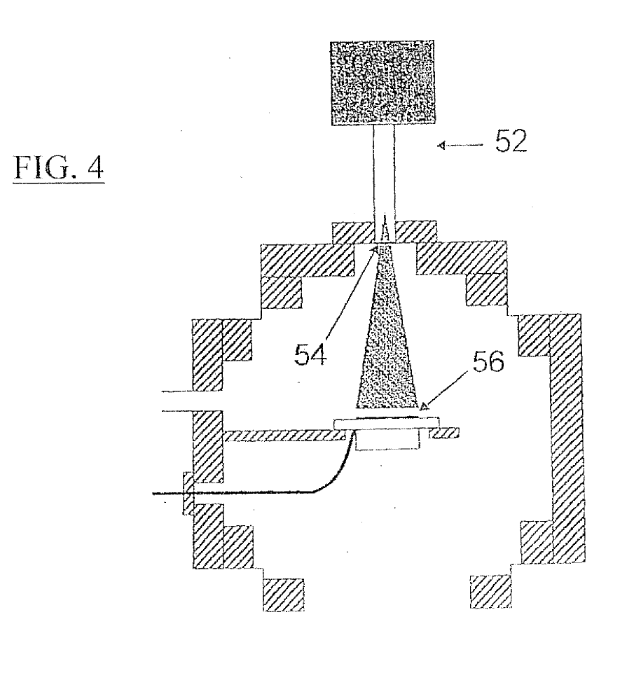

Two irradiation configurations and three different lamps were used to investigate the most effective way to perform the UV-assisted hydrogenation process. The primary difference between the two configurations was in the method of delivering the UV radiation to the sample surface. Both configurations utilized stainless steel vacuum chambers, which were evacuated and then backfilled with a hydrogenating, process gas comprising molecular hydrogen. In the first configuration the UV light source was outside the vacuum chamber and the UV radiation was transmitted into the vacuum chamber through a UV quartz viewport 13, as illustrated in FIG. 2. In the second configuration the UV lamp was mounted such that the quartz viewport 13 was not in the beam. A sketch of the second system and the sample holder is shown in FIG. 4. The lamp 52 used was a deuterium lamp made by Hamamatsu. This lamp is well suited for UV-assisted hydrogenation of semiconductor materials using deuterium and/or hydrogen. In addition to shorter wavelength output than the Hg or Xe lamps, the lamp may be mounted inside a conflat vacuum flange for direct mounting, to vacuum chamber 12. This allows direct sample illumination through a magnesium fluoride lamp window 54. As discussed above, the chamber 12 may be wrapped with heating tape and aluminum foil to achieve hydrogenation processing temperatures (60-100° C.). Sample 56 sits under UV lamp 52. This arrangement reduces viewport transmission losses, which can be significant below 200 nm.

The characteristics of the lamps used are shown in Table II.

TABLE II
A Comparison of the Three UV Sources in used in This Study

Dominant Spectral Range

| Lamp | Coupling | nm | eV |
|---|---|---|---|
| 200 W Hg | External | >230 | <5.4 |
| 150 W Xe | External | >200 | <6.2 |
| 30 W D₂ | Internal | 115-170 | 7.3-10.8 |

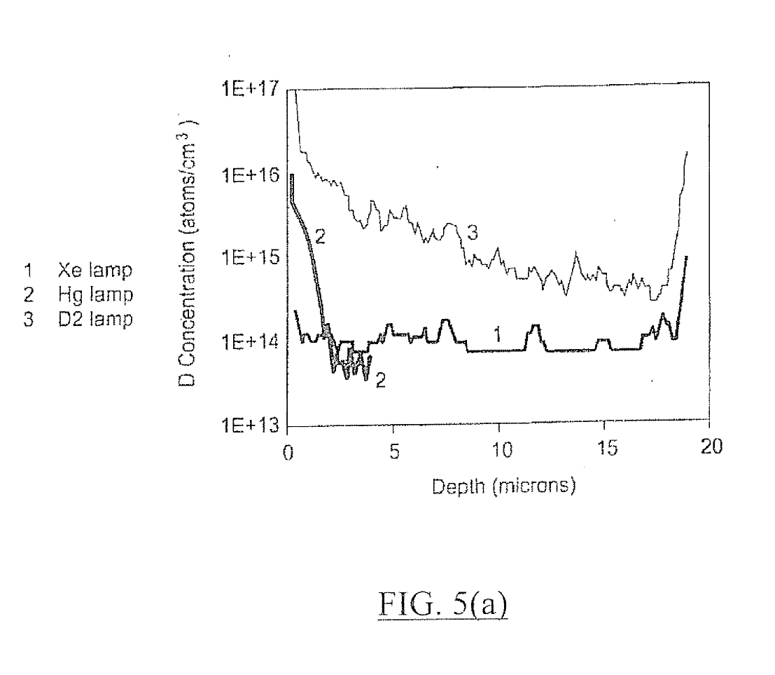

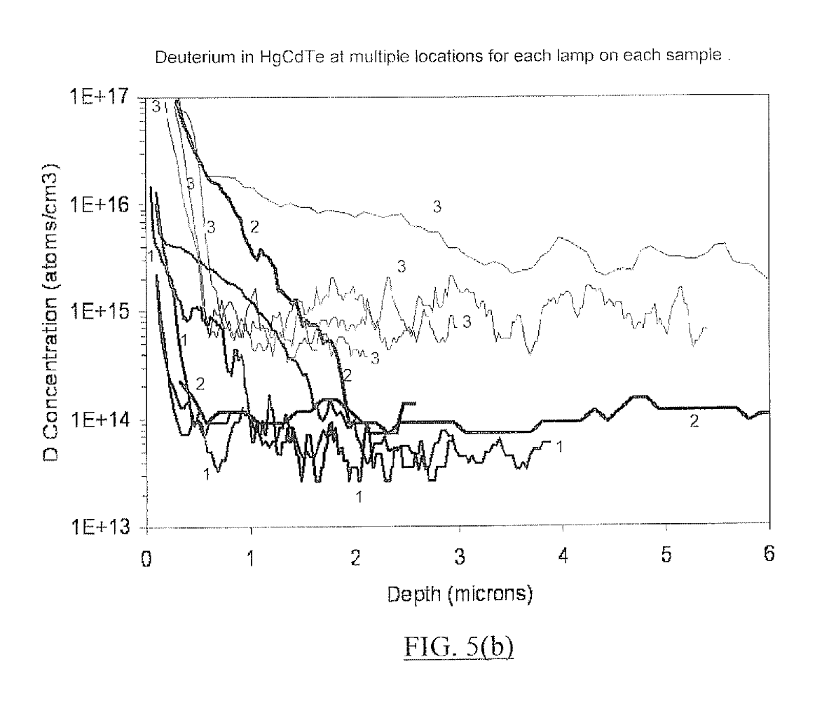

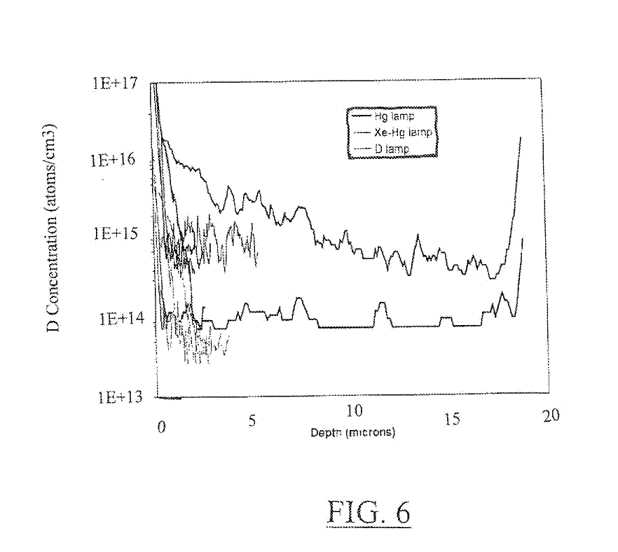

SIMS depth profiling was used to detect the presence of deuterium within the samples after UV-assisted treatment. FIG. 5a shows SIMS depth profiles for hydrogenation of HgCdTe using mercury, deuterium, and xenon lamps. Curve 1 shows data for the xenon lamp, curve 2 for the Hg lamp and curve 3 for the deuterium lamp. The deuterium lamp is effective for hydrogenation of the sample. Use of the deuterium UV source resulted in a dramatic increase in the amount of deuterium incorporation compared to similar treatments using the Hg or Xe lamps. All three samples were from the same wafer, and were given similar treatments (80° C., 48 hours) except for the UV light source. The deuterium lamp appears to be the most effective UV light source of the three lamps tested because of the natural energy resonances of the photon source with the deuterium gas present in the chamber during processing.

FIG. 5b includes the same data as FIG. 5a, except with additional traces for each type lamp. These additional traces were obtained by performing the SIMS analysis at different locations on each sample. A real variation of hydrogenation may be indicative of process non-uniformity or a reflection of non-uniformity in the sample semiconductor material. Microscope inspection of the SIMS pits to look for defects in the area under analysis showed the variations were related to the number of visible defects in the profiled area. After the SIMS depth profiling, the bottom of each milled pit was inspected for defects. These pits show that the lowest concentration profile corresponded to the lowest defect count. This correspondence between defects and deuterium concentration was consistent whenever such post-SIMS inspections were performed. Thus, the SIMS results show that (a) hydrogenation of HgCdTe can be activated by UV irradiation, (b) the concentration of D corresponds with the local defect density, and (c) the extent of hydrogenation is related to both temperature and the photon wavelength.

Use of the deuterium lamp allows the UV hydrogenation process to be studied under a completely different range of wavelengths than either the Xe or Hg lamps. The arrangement shown in FIG. 4 was used to couple the shortwave UV radiation to the sample surface.

After determining the deuterium lamp, with its primary output in the vacuum ultraviolet (VUV) range, was yielding enhanced hydrogenation compared to the Xe or Hg lamps which produce little if any VUV, portions of the original experimental work were repeated under modified conditions. This second round of experiments used the deuterium lamp inside the vacuum chamber. The second experiments also used a lower temperature range which has been found to be more benign to the fragile HgCdTe.

FIG. 3(c) shows SIMS depth profiles for three samples of HgCdTe/Si taken from the same wafer. Curve 1 of FIG. 3(c) shows the deuterium profile for a zone exposed to neither D2 or to VUV illumination. Curves 2 and 3 of FIG. 3(c) show profiles for sample zones treated in 800 torr D2 under VUV illumination from a deuterium lamp at 27 degrees Celsius for 30 hours (Curve 2) and at 52 degrees Celsius for 24 hours (Curve 3).

FIG. 3(d) shows deuterium concentration as determined by Nuclear Reaction Analysis (“NRA”) in a sample piece of HgCdTe/CdZnTe that was subjected to three (3) separate treatments with proximity masking of the VUV illumination to restrict VUV activation of the deuterium to specific zones during each treatment. The mask consisted of a movable aluminum shutter a few millimeters above the sample surface to block the illumination from any region positioned under the shutter. The lowermost zone of this sample was masked during all three treatments, and is seen to contain no detectable deuterium even though the physical arrangement of the shutter exposed it to the molecular deuterium in the chamber. Deuterium concentration is determined as total atoms per unit area over a 3 micron penetration depth, so that 10̂14/cm2 corresponds to an average density of about 3×10̂17/cm3 within the top 3 microns. All treatments were performed at room temperature which varied between 25 degrees Celsius and 27 degrees Celsius. This observation demonstrates the critical importance of the illumination (UV or VUV) in activating the deuteration process.

The hydrogenation of a selected area of the semiconductor can be improved by restriction of the UV lamp's wavelength range. A low pressure mercury lamp operating at a wavelength of 275 nm or less may be used to activate dissociation of molecular hydrogen (H₂) in the gaseous phase. Preferably a mercury lamp operating at a wavelength between 185 nm and 254 nm is ideal for dissociating molecular H₂.

The lateral diffusion of H₂ can be controlled by reducing or eliminating gas phase atomic hydrogen. Because H₂ adsorbed on the surface has smaller dissociation energy of molecular hydrogen in gas phase, a UV lamp which generates photons with a wavelength greater than 275 nm (preferably in the range of 300-400 nm) may be used for selective hydrogenation. Photons in the 300-400 nm range will only activate dissociation of adsorbed hydrogen and activate hydrogen in-diffusion without the loss of area selectivity.

Although the use of UV photo-assisted hydrogenation has been discussed with respect to HgCdTe devices to be used as IR detectors, one skilled in the art will appreciate that the systems and method disclosed herein may be used on other semiconductor devices for other uses, such as the use of hydrogenation as a self-healing mechanism for radiation hardening of HgCdTe detectors in the space environment and for other semiconductors where changes in the electrical or optical properties of the materials are needed.

The method of the present invention comprises providing a vacuum chamber 12 which may be evacuated with a turbo pump after which the sample is heated to the desired temperature and the chamber backfilled with hydrogen (or deuterium) gas. The process may be performed at atmospheric pressure, but may be done at higher and lower than atmospheric pressures as well. Further, the process gas may include mixtures of nitrogen to limit flammability of hydrogen or to control the rate of surface reactions. The UV light source may then be ignited and the sample irradiated in the deuterium environment. As discussed above, a portion of the sample may be masked to prevent irradiation of the masked portion. However, in some applications, the entire sample surface may be UV irradiated.

Using the apparatus and procedures disclosed herein a comprehensive UV Hydrogenation Parameter Matrix for HgCdTe may be developed. This will allow a user to design and tailor the hydrogenation process for the variety of HgCdTe materials encountered in various devices. HgCdTe of varying alloy content is used for NIR, SWIR, MWIR, LWIR and VLWIR. An understanding of the different parameters required for this range of HgCdTe alloys may be developed by combining data acquired from six trusts: a parameter data set for UV intensity, hydrogen pressure, temperature and time; an assessment of lateral diffusion profiles and shadow mask delineation capability; an investigation of uptake differences for the range of HgCdTe alloys used and PAH process parameters; an investigation of differences between p-type and n-type material; an investigation of H uptake in HgCdTe/Si and HgCdTe/ZnCdTe; and an investigation of uptake in HgCdTe grown by MBE and LPE.

A commercial “plug-and-play” system for Photon-Assisted Hydrogenation (PAH) for treatment of APDs or FDA's may be assembled, using a customized reaction chamber uniquely designed for PAH with masking and alignment capability. The system may comprise a chamber having a holder for supporting the material within the chamber. The UV light source is disposed to provide UV radiation on the holder within the chamber. A hydrogen gas injection system is adapted to inject molecular hydrogen gas into the chamber. UV radiation of the material and molecular hydrogen enhances absorption of atomic hydrogen by the material. The UV light source may comprise a low pressure mercury lamp configured to emit UV radiation at a wavelength in the range from 185 nm to 300 nm.

The present invention includes a method for hydrogenation of a material comprising a semiconductor 16. The method comprises providing a vacuum chamber 12 and a UV light source 11 to provide UV radiation into the chamber. Hydrogen gas is introduced into the chamber and the material is irradiated within the chamber with UV radiation with the material and hydrogen gas present within the chamber to cause absorption of the hydrogen into the material. As discussed above, the material may comprise a semiconductor. However, one skilled in the art will appreciate that UV-assisted hydrogenation may be used to hydrogenate a metal, ceramic, or carbon-based material. The method may further comprise controlling a temperature of the material within a selected range preferable below 900 degrees Celsius and more preferably at room temperature. In accordance with the method of the present invention the hydrogen gas may comprise molecular hydrogen which is dissociated within the chamber as a result of its exposure to the UV radiation. The dissociation of the molecular hydrogen may include dissociation of the molecular hydrogen adsorbed to the surface of the material. A benefit of UV-assisted dissociation of adsorbed hydrogen is the formation of neutral atomic hydrogen

In accordance with the present invention, defect passivation by UV-activated hydrogenation is quite effective in HgCdTe. Hydrogen passivation appears to be selective to deep-levels associated with defects rather than shallow impurity levels. Thus, hydrogenation effectively deactivates defects without affecting dopant activity so that device functionality is not adversely affected. Instead, hydrogenation has been shown to improve the operating parameters of HgCdTe-based optoelectronic devices including significant reduction in dark current and increase in quantum efficiency. Also, since HgCdTe is not available as a bulk crystal, it is grown epitaxially on a suitable single-crystal substrate. A nearly lattice-matched CdTe substrate has been used for this purpose, as well as bulk Si, which is poorly lattice-matched to HgCdTe. The dislocation density in epitaxial films of HgCdTe grown on these substrates varies widely due to the degree of lattice matching. Nonetheless, hydrogenation has been shown to be effective irregardless of the material quality of HgCdTe, i.e. the substrate used for growth.

Uptake of hydrogen in HgCdTe during UV irradiation was found to depend strongly upon the spectra output of the UV lamp, which is consistent with the previous discussion. 30 W D₂ UV source produced significant in-diffusion of deuterium into HgCdTe. Temperature was also investigated and found to play a significant role in hydrogenation. Irradiation using either the Hg or Xe lamps resulted in little or no detectable D in the samples during hydrogenation below 60° C. as seen in FIG. 8. However, significant in-diffusion of deuterium was observed after UV-irradiation with the deuterium lamp even at room temperature (not shown). This provides an indication that UV-irradiation may provide enhancement of reactions beyond those at the surface that influence hydrogen in-diffusion.

Thus, the absence of dopant deactivation during hydrogenation of HgCdTe may be due to the unique properties of UV-activated process rather than common to all hydrogenation techniques. Most semiconductors possess open lattices such as the diamond, zinc blend or the wurzite, which allow atomic hydrogen to dissolve and quickly diffuse interstitially. The equilibrium concentration of dissolved hydrogen depends on charge state (±, o), as determined by the Fermi energy in the semiconductor. In general, dissolved hydrogen tends to reduce the conductivity of the semiconductor, so that the H⁻ acceptor is predominately found in n-type material, and the H⁺ donor in p-type. It should be understood that H⁺ diffuses substantially faster than either of its other forms simply because it is physically much smaller. Alternatively, there are other pathways for hydrogen diffusion in semiconductors such as along dislocations where open volume within the core of the dislocation readily provides a ‘short-circuit’ pathway for hydrogen in-diffusion.

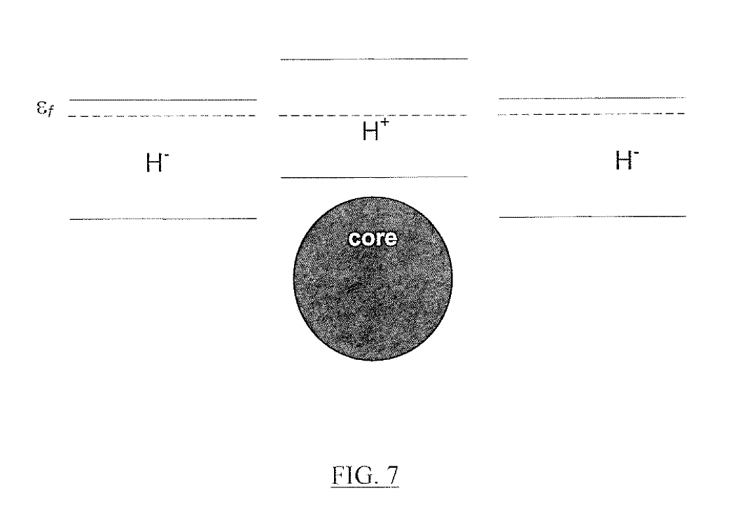

Injection of ‘hot’ electrons during UV-irradiation may confine hydrogen in-diffusion mostly to dislocations. These injected electrons create a quasi-equilibrium, n-type region over their diffusion length in the material (7-10 μm in HgCdTe.) This occurs everywhere in the sample except at the locations where dislocations intersect the surface. Here the Fermi level is pinned near the middle of the band gap as a result of the high density of defects within the dislocation core. A simple band structure diagram near a dislocation core is shown in FIG. 7. The variation of the Fermi level changes the character of hydrogen in-diffusion due to its effect on the equilibrium charge-state of hydrogen, which changes from H⁻ (in the n-type bulk) to H⁺ within the dislocation core. The negatively charged hydrogen in the bulk is essentially immobile due to its size, such that little or no hydrogen in-diffusion occurs via this pathway, other than near the surface where there is a predominance of residual holes. Therefore, electron injection during UV-activated in-diffusion of hydrogen results in a strong preference for hydrogen to diffuse along dislocations and not within the crystal bulk. This preference is related to the charge state of the diffusing hydrogen ion, which determines its size and therefore its rate of diffusion within the lattice. It should be mentioned that this effect is distinct from that normally associated with dislocations, which provide pathways for fast diffusion in semiconductors. The effect of charge-state substantially retards bulk diffusion and may be responsible for the absence of dopant deactivation in HgCdTe. The absence of dopant deactivation during UV-activated hydrogenation may be a general effect that occurs generally within semiconductors (and not limited to HgCdTe).

Furthermore, the separation of the photo-generated electron-hole pairs creates an internal field in the semiconductor that is directed into the sample. This field acts to retard the motion of H⁻ ions and ensures little or no bulk diffusion of hydrogen.

Hydrogenation may be also used to influence the electrical properties of Group IV semiconductors (silicon or germanium), and Group III-V semiconductors (GaAs, InSb, and AlSb), as well as a number of heterostructure systems including GaAs/Si, GaAs/InP, among others (such as hydrogenation to improve the performance of polycrystalline-silicon solar cells).

Hydrogenation of semiconductor materials, and particularly HgCdTe, has been disclosed herein. It should be understood, however, that the same process may be applied to other materials that may benefit from hydrogenation. For example, ceramics, metals, carbon structures (such as graphite, natural or synthetic diamond and carbon-60 structures) and other materials may be hydrogenated more effectively by application of the photo-assisted process described herein. Further, selected areas of a material may be hydrogenated by the methods disclosed herein.

Although the present invention has been described with reference to specific details, it is not intended that such details should be regarded as limitations on the scope of the invention, except to the extent that they are included in the claims.

1. A method for passivating defects of a material, the method comprising:
providing a chamber and a UV light source to provide UV radiation in the chamber;
placing the material into the chamber;
introducing a hydrogenating gas into the chamber; and
irradiating the material within the chamber with UV radiation with the material and hydrogenating gas present within the chamber to cause absorption of the hydrogenating gas into the material.

2. The method of claim 1 wherein the material comprises a Mercury Cadmium Telluride semiconductor.

3. The method of claim 1 further comprising controlling a temperature of the material within a selected range.

4. The method of claim 1 wherein the UV light source comprises a UV-lamp.

5. The method of claim 1 wherein the hydrogenating gas comprises molecular hydrogen, the method further comprising disassociating the molecular hydrogen within the chamber as a result of its exposure to the UV radiation.

6. The method of claim 5 further comprising dissociating the molecular hydrogen on a surface of the material.

7. The method of claim 5 wherein dissociating the molecular hydrogen generates only neutral atomic hydrogen.

8. The method of claim 1 wherein the hydrogenating gas comprises deuterium.

9. The method of claim 1 further comprising maintaining a temperature of the material at a constant value.

10. The method of claim 9 wherein the constant value is at or below 100 degrees Celsius.

11. The method of claim 1 further comprising masking a portion of the material prior to irradiating the material.

12. The method of claim 1 wherein the material comprises a metal, ceramic, or carbon-based material.

13. The method of claim 1 further comprising injecting electrons during the step of irradiating the material.

14. The method of claim 8 wherein the material comprises a Mercury Cadmium Telluride semiconductor.

15. A method for passivation of defects in an optoelectric device, the method comprising:
providing a vacuum chamber adapted to support the optoelectric device;
providing a UV light source;
placing the optoelectric device within the chamber and introducing a hydrogenating gas into the chamber;
adsorbing the hydrogenating gas to a surface of the optoelectric device;
irradiating the hydrogenating gas and the hydrogenating gas adsorbed to the surface of the optoelectric device to dissociate the hydrogenating gas to generate atomic components;
injecting electrons into the vacuum chamber during the step of irradiating the hydrogenating gas; and
absorbing the atomic components within the optoelectric device to passivate at least one defect center within the optoelectric device.

16. The method of claim 15 further comprising maintaining a temperature of the optoelectric device during adsorbing, irradiating and absorbing at or below 100 degrees Celsius.

17. The method of claim 15 wherein the hydrogenating gas comprises hydrogen gas.

18. The method of claim 17 wherein the step of irradiating the hydrogen gas generates neutral atomic hydrogen.

19. The method of claim 15 wherein the optoelectric device comprises a plurality of dislocation defects.

20. The optoelectric device of claim 19 wherein the optoelectric device comprises an HgCdTe material.

21. A Mercury Cadmium Telluride optoelectric device structure comprising a plurality of passivated dislocation defects, wherein the dislocation defects have been passivated by the introduction of hydrogen into the dislocation core.
